(19) United States
(12) Patent Application Publication
(10) Pub. No.: US 2024/0260402 A1
(43) Pub. Date: Aug. 1, 2024

(54) COVER PLATE MODULE AND DISPLAY APPARATUS INCLUDING THE SAME

(71) Applicant: LG Display Co., Ltd., Seoul (KR)

(72) Inventor: Sang Won KIM, Paju-si (KR)

(21) Appl. No.: 18/417,861

(22) Filed: Jan. 19, 2024

(30) Foreign Application Priority Data
Jan. 31, 2023 (KR) 10-2023-0012654

(51) Int. Cl. H10K 59/80

(52) U.S. Cl. CPC H10K 59/873; H10K 59/8791; H10K 59/8794

(57) ABSTRACT

The present disclosure relates to a cover plate module and a display apparatus including the same. Disclosed is a cover plate module including a cover plate including a transparent part, an anti scattered film located on the cover plate, and a metal fine line assembly provided on the anti scattered film. The cover plate module and a display apparatus including the same ensure uniform heat dissipation between the front surface and the rear surface of the display apparatus, thus preventing occurrence of a warpage defect and improving reliability of the display apparatus.

### CROSS-REFERENCE TO RELATED APPLICATION

This application claims the benefit of Korean Patent Application No. 10-2023-0012654, filed on Jan. 31, 2023, which is hereby incorporated by reference as if fully set forth herein.

### BACKGROUND

### Technical Field

The present disclosure relates to a cover plate module and a display apparatus including the same.

### Description of the Related Art

As the information society develops, demand for display apparatuses for displaying images is increasing in various forms.

Application of display apparatuses is extending not only to computer monitors and TVs but also to personal mobile devices.

Recently, a display apparatus functions as a single apparatus, and is also combined with several electronic apparatuses or equipment so as to be used to display status. Further, research on display apparatuses including light emitting devices on a substrate so as to have a large display area and reduced volume and weight for ease in combination are underway.

### BRIEF SUMMARY

Accordingly, the present disclosure is directed to a cover plate module and a display apparatus including the same that substantially obviate one or more problems due to limitations, and disadvantages of the related art.

In a display apparatus, a cover plate is located on a display panel, and a heat sink and the like are located under the display panel. Due to a heat dissipation characteristic difference between the cover plate and the heat sink, when the display apparatus is in a high-temperature state, the heat sink having relatively high heat dissipation efficiency contracts and the cover plate having relatively low heat dissipation efficiency expands, and thus, the display apparatus may warp in the downward direction when viewed in a cross section.

Various embodiments of the present disclosure provide a display apparatus which solves a warpage defect due to a temperature change and thus has improved reliability.

The technical benefits to be accomplished by the present disclosure are not limited to the above-mentioned benefits, and other benefits not mentioned herein will be clearly understood by those skilled in the art from the following description.

Additional advantages, benefits, and features of the disclosure will be set forth in part in the description which follows, and in part will become apparent to those having ordinary skill in the art upon examination of the following or may be learned from practice of the disclosure. The benefits, and other advantages of the disclosure may be realized, and attained by the structure particularly pointed out in the written description, and claims hereof as well as the appended drawings.

To achieve these benefits and other advantages and in accordance with the purpose of the disclosure, as embodied and broadly described herein, a cover plate module includes a cover plate including a transparent part, an anti scattered film located on the cover plate, and a metal fine line assembly provided on the anti scattered film.

In another aspect, a display apparatus includes at least one display panel, a cover plate module provided on the least one display panel and including a cover plate and a metal fine line assembly provided on the cover plate, a bottom plate provided under the at least one display panel so as to support the at least one display panel, and a heat sink located under the bottom plate.

The details of other embodiments are included in the following description and the drawings.

It is to be understood that both the foregoing general description, and the following detailed description of the present disclosure are exemplary, and explanatory, and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure, and are incorporated in, and constitute a part of this application, illustrate embodiment(s) of the disclosure, and together with the description serve to explain the principle of the disclosure. In the drawings:

FIG. 1 is a view showing an example of use of a display apparatus according to one embodiment of the present disclosure;

FIG. 2 is a cross-sectional view showing the display apparatus according to one embodiment of the present disclosure;

FIG. 3 is a perspective view showing the configuration of a protective film formed on a cover plate shown in FIG. 2;

FIG. 4 is a cross-sectional view showing one portion of the protective film shown in FIG. 2;

FIG. 5 is a cross-sectional view showing a display apparatus according to another embodiment of the present disclosure;

FIG. 6 is a plan view showing the cover plate of the display apparatus according to one embodiment of the present disclosure;

FIG. 7 is a perspective view showing a method of manufacturing a cover plate module (a cover plate assembly) according to the present disclosure;

FIG. 8 is a perspective view showing a display panel of the display apparatus according to the present disclosure;

FIG. 9 is a cross-sectional view taken along line I-I′ of FIG. 8;

FIG. 10 is a block diagram schematically showing the display panel shown in FIG. 8;

FIG. 11 is a plan view showing a display apparatus according to another embodiment of the present disclosure;

FIG. 12 is a cross-sectional view taken along line II-II′ of FIG. 11;

FIG. 13 is a cross-sectional view showing a cover plate module according to yet another embodiment of the present disclosure; and

FIG. 14 is a view showing temperature changes of cover plate modules of display apparatuses according to Test Example 1 and Test Example 2 of the present disclosure after a high-temperature driving test.

### DETAILED DESCRIPTION

Advantages and features of the present disclosure, and implementation methods thereof will be clarified through the following embodiments described with reference to the accompanying drawings. The present disclosure may however, be embodied in different forms, and should not be construed as limited to the embodiments set forth herein. Rather, these embodiments are provided so that this disclosure will be thorough, and complete, and will fully convey the scope of the present disclosure to those skilled in the art, and the present disclosure is only defined by the scope of claims.

The shapes, sizes, dimensions (e.g., length, width, height, thickness, radius, diameter, area, etc.), ratios, angles, numbers, number of elements, and the like disclosed in the drawings for describing various embodiments of the present disclosure are merely examples, and thus, the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure aspects of the present disclosure, the detailed description will be omitted. When “comprise,” “have,” and “include” described in the present disclosure are used, another part may be added unless “only” is used. Terms in a singular form may include plural forms unless stated to the contrary.

In construing an element, the element is construed as including an error or tolerance range although there is no explicit description of such an error or tolerance range.

In describing a positional relationship, for example, when a positional relation between two parts is described as, for example, “on,” “over,” “under,” and “next,” one or more other parts may be disposed between the two parts unless a more limiting term, such as “just” or “direct(ly)” is used.

In describing a temporal relationship, for example, when the temporal order is described as, for example, “after,” “subsequent,” “next,” and “before,” a situation that is not continuous may be included unless a more limiting term, such as “just” or “direct(ly)” is used.

It will be understood that, although the terms “first,” “second,” etc., may be used herein to describe various elements, these elements should not be limited by these terms. These terms are only used to distinguish one element from another, and may not define order. For example, a first element could be termed a second element within the scope of the present disclosure.

In describing elements of the present disclosure, the terms “first,” “second,” “A,” “B,” “(a),” “(b),” etc., may be used. These terms are only used to distinguish the elements from other elements, and the natures, turns, orders, or numbers of the corresponding elements are not limited by the terms. When an element or layer is referred to as being “connected to” or “coupled to” another element or layer, it may be directly connected or coupled to the other element or layer, or intervening elements or layers may be present between the respective elements or layers connected or coupled to each other unless explicitly stated otherwise.

The term “at least one” should be understood as including all combinations presented by one or more of associated elements. For example, “at least one of a first element, a second element or a third element” may not only mean the first element, the second element or the third element, respectively, but also mean all combinations presented by two or more of the first element, the second element and the third element.

As used herein, the term “display apparatus” may include a display apparatus, such as a liquid crystal module (LCM), an organic light emitting diode (OLED) module or a quantum dot (QD) module including a display panel and a driver configured to drive the display panel, in a narrow sense. Further, it may include a complete product or a final product including an LCM, an OLED module or a QD module, such as a notebook computer, a TV, a computer monitor or an automotive display apparatus, or a set electronic apparatus or a set apparatus, such as an equipment display apparatus including other type of vehicle, a mobile electronic apparatus, such as a smartphone or an electronic pad.

An automotive display apparatus may refer to a display apparatus mounted or incorporated into an automotive (e.g., an automobile). An automobile may include a body having a motor mounted therein. The motor may include an electric motor. Here, at least one display panel of the display apparatus may be mounted, included or incorporated in the body of the automobile.

Therefore, in the following description of the present disclosure, the term “display apparatus” may not only include a display apparatus itself, such as an LCM, an OLED module or a QD module, in a narrow sense, but also include an application product including an LCM, an OLED module or a QD module or a set apparatus which is a final consumer apparatus.

In some cases, an LCM, an OLED module or a QD module including a display panel and a driver may be expressed as a “display apparatus” in a narrow sense, and an electronic apparatus, which is a final product, including an LCM, an OLED module or a QD module may be expressed as a “set apparatus,” separately. For example, a display apparatus in a narrow sense may include a display panel including liquid crystal devices (LCDs), organic light emitting diodes (OLEDs) or quantum dot devices, and a source PCB which is a controller configured to drive the display panel, and a set apparatus may further include a set PCB which is a set controller conductively connected to the source PCB so as to control the entirety of the set apparatus.

A display panel used in one embodiment of the present disclosure may employ any type of display panel, such as a liquid crystal display panel, an organic light emitting diode (OLED) display panel, a quantum dot (QD) display panel or an electroluminescent display panel. The display panel in this embodiment of the present disclosure includes a flexible substrate for organic light emitting diode (OLED) display panels, and a support member support structure disposed thereunder, and is not limited to a specific display panel enabling bezel bending. Further, the shape or size of a display panel used in a display apparatus according to one embodiment of the present disclosure is not limited.

For example, when the display panel is an organic light emitting diode (OLED) display panel, the display panel may include a plurality of gate lines, a plurality of data lines, and pixels formed in intersection areas between the gate lines and/or the data lines. Further, the display panel may include an array including thin film transistors which are devices configured to selectively apply voltage to the respective pixels, a light emitting diode layer, and an encapsulation substrate or an encapsulation layer disposed on the array so as to cover the light emitting diode layer. The encapsulation layer may protect the thin film transistors and the light emitting diode layer from external impact, and may prevent moisture or oxygen from penetrating the light emitting diode layer. Further, a layer formed on the array may include an inorganic light emitting layer, for example, a nano-sized material layer or quantum dots.

Respective features of various embodiments of the present disclosure may be partially or wholly coupled to or combined with each other, and may be technically variously inter-operated with each other and driven, and the respective embodiments of the present disclosure may be implemented independently of each other, or may be implemented together in a co-dependent manner.

Hereinafter, exemplary embodiments of the present disclosure will be described in detail with reference to the accompanying drawings. Elements illustrated in the accompanying drawings may have scales different from the actual scales thereof for convenience of explanation, and are thus not limited to the scales illustrated in the drawings.

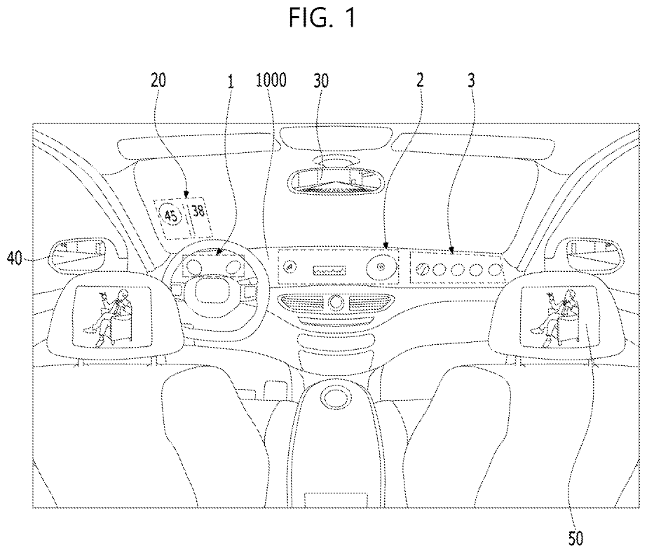

FIG. 1 is a view showing an example of use of a display apparatus according to one embodiment of the present disclosure.

As shown in FIG. 1, a display apparatus 1000 according to one embodiment of the present disclosure may be disposed on a dashboard of a vehicle. The dashboard of the vehicle may have elements disposed on a plane in front of front seats (a driver's seat and a front passenger seat) of the vehicle. Further, input elements configured to operate various functions in the vehicle may be disposed on the dashboard of the vehicle.

As shown in FIG. 1, the display apparatus 1000 according to one embodiment of the present disclosure may include a first display 1 including an instrument panel indicating a vehicle speed, a fuel amount, a vehicle interior temperature, the state of an air conditioner, etc., a second display 2 including an audio system displaying a radio frequency or a sound volume and a sound source list from a storage medium through a displayed image, and a third display 3 configured to indicate states of various systems in the vehicle. In addition, the display apparatus 1000 may further include a navigation system configured to provide directions, and traffic information to a user, and may provide various information about the vehicle, for example, driving information of the vehicle (for example, a current speed of the vehicle, a remaining fuel amount, and a mileage), and information about parts of the vehicle (for example, damage degrees of vehicle tires).

According to one embodiment of the present disclosure, as shown in FIG. 1, the display apparatus 1000 may be disposed to extend horizontally so as to face both the driver's seat and the front passenger seat, may provide images both to a driver and a passenger seated in the front passenger seat of the vehicle, and may display corresponding images depending on user operation of the display apparatus 1000.

The display apparatus 1000 according to one embodiment of the present disclosure is not limited to the area of the dashboard of the vehicle.

As shown in FIG. 1 the display apparatus 1000 according to one embodiment of the present disclosure may further include a fourth display 20 configured to provide vehicle driving-related information to a vehicle windshield facing the driver.

Further, as shown in FIG. 1, the display apparatus 1000 according to one embodiment of the present disclosure may further include at least one a fifth display 30 provided on a rear-view mirror configured to display an area located at the rear of the vehicle, sixth displays 40 provided on side-view mirrors configured to display areas on the sides of the vehicle, or seventh displays 50 configured to display an image to passengers seated in the rear seat of the vehicle.

The fifth display 30 and the sixth displays 60 may provide information about structures approaching the vehicle, distances between the vehicle and other vehicles, and the speeds of the other vehicles, and may be provided in only some areas of the corresponding mirrors within levels which do not impede the functions of the corresponding mirrors.

Display apparatuses according to embodiments of the present disclosure may be applied not only to the dashboard of a vehicle but also to displays disposed in various areas of the vehicle. Further, the display apparatuses according to the present disclosure are not limited thereto, and may be applied to an apparatus which is not mounted in a vehicle, and is possessed by a user so as to be used.

Hereinafter, for example, a display apparatus mounted in a vehicle will be described. The display apparatus mounted in the vehicle is only one example for description of the present disclosure, but the embodiments of the present disclosure are not limited thereto.

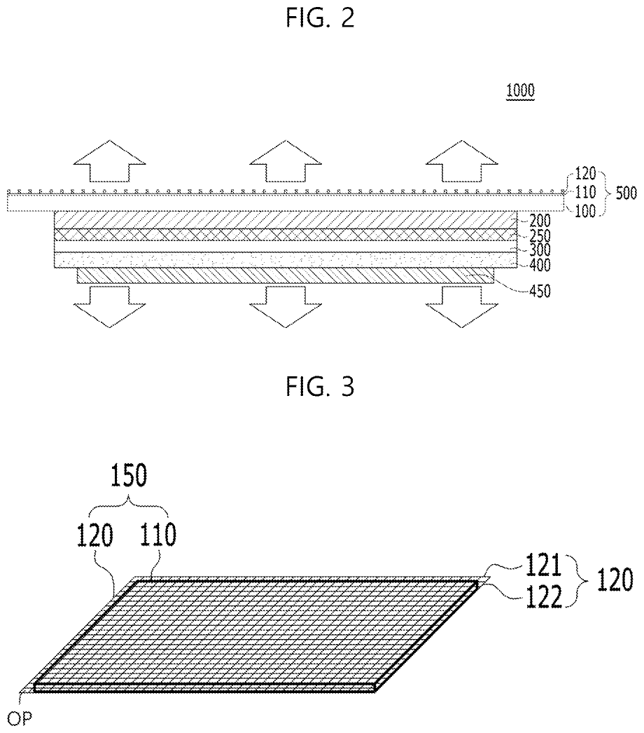

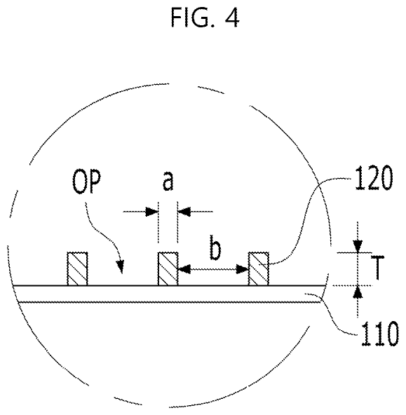

FIG. 2 is a cross-sectional view showing the display apparatus according to one embodiment of the present disclosure. FIG. 3 is a perspective view showing the configuration of a protective film formed on a cover plate shown in FIG. 2. FIG. 4 is a cross-sectional view showing one portion of the protective film shown in FIG. 2.

As shown in FIG. 2, the display apparatus 1000 according to one embodiment of the present disclosure may include a display panel 300, a cover plate module 500 provided on the display panel 300 and including a cover plate 100 and a metal fine line unit 120 on the cover plate 100, a bottom plate 400 provided under the display panel 300 so as to support the display panel 300, and a heat sink 450 located under the bottom plate 400. The metal fine line unit 120 is an assembly of a structures and thus can also be called a metal fine line assembly 120.

The cover plate module 500 is located on an emission surface of the display panel 300 which emits light. The cover plate module 500 is provided to face a user, and functions to protect lower elements from external physical stimulation. Further, in one embodiment of the present disclosure, the cover plate module (cover plate unit) 500 is referred to as a cover plate module in that the cover plate 100, the metal fine line unit 120 and an anti scattered film (or “shatterproof film”) 110 are integrated into one module.

The cover plate module 500 according to one embodiment of the present disclosure may further include the anti scattered film 110 provided between the transparent cover plate 100 and the metal fine line unit 120.

For example, the cover plate 100 may be formed of transparent glass, or a transparent film having a designated thickness. At least one active area of the cover plate 100 may include a transparent part. Other areas of the cover plate 100, which do not correspond to the active area, may include an ink material and may thus not be transparent. For example, when transparent members included in the vehicle include a rigid material, such as glass, the transparent members may shatter due to external impact, and therefore, the anti scattered film 110 may be provided on at least one surface of the cover plate 100 so as to prevent shattered components from scattering.

In this case, the cover plate module 500 may include the cover plate 100, the anti scattered film 110 located on the cover plate 100, and the metal fine line unit 120 provided on, namely, positioned and located on, the anti scattered film 110.

According to one embodiment of the present disclosure, as shown in FIGS. 2 to 4, the metal fine line unit 120 may include a plurality of first fine lines 121 and a plurality of second fine lines 122 arranged in a first direction and a second direction intersecting each other, and a plurality of openings OP provided between the plurality of first fine lines 121 and the plurality of second fine lines 122 intersecting each other.

According to one embodiment of the present disclosure, as shown in FIGS. 3, and 4, the plurality of first fine lines 121 and the plurality of second fine lines 122 may have a width a of 5 μm to 10 μm and a thickness T of 1 μm to 3 μm, respectively, and the width b of the plurality of openings OP may be greater than the width of each of the plurality of first fine lines 121 and the plurality of second fine lines 122. The embodiments of the present disclosure are not limited thereto. More preferably, the width b of the openings OP between the first and second fine lines 121 and 122 may be 5 times to 10 times the width a of the first and second fine lines 121 and 122. For example, an image transmitted from the display panel 300 may be transmitted at a transmittance of 85% or more through the openings OP provided in the metal fine line unit 120.

According to one embodiment of the present disclosure, a first surface of the anti scattered film 110 may come into contact with the cover plate 100, and a second surface of the anti scattered film 110 may come into contact with the metal fine line unit 120. The metal fine line unit 120 may be formed on the anti scattered film 110 without any separated adhesive, and the anti scattered film 110 may be adhered to the cover plate 100 by removing a release film from the lower surface of the anti scattered film 110 and then adhering the lower surface of the anti scattered film 110, i.e., an exposed adhesive surface of the anti scattered film 110, directly to the cover plate 100.

The metal fine line unit 120 may formed directly on a protective film provided on the cover plate 100 and may thus do not require a separate adhesive layer, and the pattern itself of the metal fine line unit 120 contributes to heat dissipation and therefore the metal fine line unit 120 may solve temperature deviations among areas of the cover plate 100 without requiring application of an electrical signal.

The planar area of the metal fine line unit 120 may be less than the planar area of the anti scattered film 110. The reason for this is that the metal fine line unit 120 has the openings OP. In some cases, the overall size of the metal fine line unit 120 may be reduced compared to the overall size of the anti scattered film 110. The metal fine line unit 120 serves to make the contraction amount of the element under the display panel 300 and the contraction amount of the cover plate module 500 similar to each other, and the metal fine line unit 120 may not completely overlap the anti scattered film 110.

According to one embodiment of the present disclosure, the metal fine line unit 120 may be formed of a metal or a metal alloy including at least one of copper, aluminum, gold, silver, or tungsten. Such a metal or metal alloy has thermal conductivity of 60 kcal/° C. or more, which is higher than the thermal conductivity of the transparent cover plate 100, and thus, the metal fine line unit 120 serves to complement low heat dissipation of the cover plate 100 in the cover plate module 500 formed by adhering the metal fine line unit 120 to the cover plate 100 by the anti scattered film 110.

Further, an integration of the anti scattered film 110 and the metal fine line unit 120 is referred to as a protective film 155 in that it functions to protect the cover plate 100.

FIG. 2 shows that heat dissipation of the cover plate module 500 including the metal fine line unit 120 is equal to the heat dissipation of the heat sink 450 located below the display panel 300 according to one embodiment of the present disclosure.

The metal fine line unit 120 of the present disclosure may include a metal having higher thermal conductivity so as to have similar heat dissipation to the heat sink 450. The reason for this is that the metal fine line unit 120 is patterned to form the openings OP and the heat sink 450 has a plate shape.

Because the display panel 300 itself includes light emitting diodes, and transistors connected to the light emitting diodes and drivers configured to supply signals to the transistors are located at one side of the display panel 300, there are a lot of heat-producing elements among the elements of the display apparatus 1000. Further, the drivers of the display panel 300 are received in the lower surface of the display panel 300 opposite the display surface of the display panel 300, and therefore, the heat sink 450 configured to dissipate heat to the outside may be further provided under the bottom plate 400 in addition to the bottom plate 400 provided under the display panel 300 so as to support the display panel 300. The heat sink 450 may include a material facilitating heat dissipation. The heat sink 450 may formed of, for example, a metal such as aluminum easily manufactured into the heat sink 450 through sheet metal processing, and may rapidly dissipate heat generated from the display panel 300 to the outside.

The bottom plate 400 may be disposed under the display panel 300. The bottom plate 400 may be adhered to the lower surface of the display panel 300 so as to prevent the display panel 300 from being warped and damaged. For example, the bottom plate 400 may reinforce rigidity of the display panel 300.

The bottom plate 400 may be provided, for example, in a film type, and may be adhered to the display panel 300. However, the bottom plate 400 is not limited thereto.

The bottom plate 400 may be adhered to one (i.e., a second surface) out of both surfaces of a base material of the display panel 300, opposite to the other (i.e., a first surface) having the light emitting diodes provided thereon. The bottom plate 400 may be formed of a thin film including a combination of polyethylene naphthalate (PEN), polyethylene terephthalate (PET), polyethylene ether phthalate, polycarbonate, polyacrylate, polyether imide, polyether sulfonate, polyimide, polyacrylate, and/or other proper polymers. Otherwise, the bottom plate 400 may be formed of thin glass, metal foil shielded by a dielectric, a multilayer polymer film, or a polymer film including a polymer material combined with nanoparticles or microparticles. The bottom plate 400 may have a greater thickness than the base material of the display panel 300 so as to have support force. However, the embodiments of the present disclosure are not limited thereto.

When the display apparatus 1000 includes the bottom plate 400, the rear surface of the display panel 300 may be adhered to the bottom plate 400, and thereafter, a process of coupling the heat sink 450 to the display panel 300 having bottom plate 400 may be performed. The embodiments of the present disclosure are not limited thereto.

The heat sink 450 may be effective in dissipation of heat produced due to spontaneous driving of the display panel 300, but because the cover plate 100 having low thermal conductivity is disposed on the upper surface of the display panel 300 opposite the lower surface of the display panel 300, in the case in which the cover plate 100 does not have the metal fine line unit 120 of the present disclosure, a difference in heat transfer stress occurs, the element adjacent to the heat sink 450 having rapid heat dissipation contracts and the cover plate 100 having slow heat dissipation expands due to a high temperature, and thus, the display apparatus 1000 may sag downward. For example, in a display apparatus without a metal fine line unit, a warpage defect may occur due to a heat dissipation rate difference caused by a contraction amount difference between a cover plate and a heat sink in a high-temperature environment.

Further, the warpage defect may become worse when the display apparatus is exposed to an outdoor environment in hot weather and thus a high temperature is maintained, or when the display panel 300 continues to be driven at a high speed.

As shown in FIG. 2, the display apparatus 1000 according to one embodiment of the present disclosure has the metal fine line unit 120 provided as the uppermost layer of the cover plate module 500 so as to allow the cover plate module 500 to have heat dissipation efficiency equivalent to the heat dissipation efficiency of the heat sink 450.

The metal fine line unit 120 is patterned to form the openings OP therein, and for example, may be formed of a metal or a metal alloy having a greater heat transfer rate than a metal forming the plate-type heat sink 450.

Further, location of the metal fine line unit 120 as the uppermost layer of the cover plate module 500 is effective in that, when a warpage defect occurs in the downward direction, the metal fine line unit 120 provides heat dissipation properties in the opposite direction, and may thus prevent the cover plate 100 from expanding.

Further, as shown in FIG. 2, a polarizing plate 250, and a functional film 200 may be provided between the display panel 300 and the cover plate 100.

Here, the polarizing plate 250 is provided to prevent reflection due to incidence of external light upon the display panel 300. The polarizing plate 250 may control display characteristics, for example, reflection of external light, compensation of color accuracy, and improvement in luminance.

Further, the functional film 200 may include an optical angle adjustment structure configured to adjust the visible range of an image displayed on the display panel 300, or a touch functional unit. The optical angle adjustment structure may be provided as a trapezoidal pattern, the angle of which is adjusted so as to correspond to a desired visible range when viewed in a cross section thereof, within the functional film 200. The trapezoidal pattern may be formed of a light-shielding material, but the embodiments of the present disclosure are not limited thereto. In some cases, the functional film 200 may not be separately provided, and may be patterned and included in the uppermost layer of the display panel 300 or the inner surface of the cover plate 100. In some cases, the functional film 200 may not be provided in the display apparatus 1000. The embodiments of the present disclosure are not limited to the configuration of FIG. 2 in relation to the functional film 200 and the polarizing plate 250. When the functional film 200 is provided, an adhesive layer may be further provided between the functional film 200 and the cover plate 100.

The cover plate module 500 is located at the outermost part of the display apparatus 1000, and may have a sufficiently greater area than the display panel 300 so as to sufficiently protect the lower elements. Therefore, as shown in FIG. 2, the cover plate 100 is formed to have a greater area than the display panel 300, and protrudes farther outwards than the edge of the display panel 300. Further, the cover plate module 500 of the display apparatus 1000 according to one embodiment of the present disclosure may have the anti scattered film 110 and the metal fine line unit 120 formed to have the same area as the cover plate 100, so as to dissipate heat from all areas of the cover plate 100.

The display apparatus 1000 according to one embodiment of the preset disclosure have the metal fine line unit 120 provided at the uppermost part of the cover plate 100 so as to supplement the low heat transfer rate of the cover plate 100, thereby being capable of adjusting the heat dissipation of the cover plate module 500 to a level similar to the heat dissipation of the heat sink 450. The cover plate module 500 according to one embodiment of the present disclosure may increase a heat dissipation rate throughout the entire surfaces of the cover plate 100 using the thermal conductivity of the metal forming the metal fine line unit 120.

Further, the display apparatus 1000 according to one embodiment of the present disclosure makes the heat dissipation rates through the front and rear surfaces of the cover plate 100 the same, and thereby, warpage or sagging of the display apparatus 1000 in a specific direction may be prevented.

The cover plate module 500 and the display apparatus 1000 including the same according to one embodiment of the present disclosure have the openings OP having a greater width (spacing) b than the width a of the metal lines of the metal fine line unit 120 which performs heat dissipation, thereby maintaining a transmittance of a designated level or more. Therefore, the display function of the display panel 300 coupled to the cover plate module 500 may not be deteriorated.

The cover plate module 500 and the display apparatus 1000 including the same according to one embodiment of the present disclosure may have the metal fine line unit 120 formed of a metal used in the display apparatus field, and may use eco-friendly materials without using hazardous substances. Further, the metal fine line unit 120 may be formed directly on the anti scattered film 110 functioning as a protective film provided on the cover plate 100, and may thus contribute to heat dissipation through the pattern itself of the metal fine line unit 120 without requiring any separate adhesive layer, thus being capable of solving temperature deviations among areas of the cover plate 100 without requiring application of an electrical signal

Further, the cover plate module 500 and the display apparatus 1000 including the same according to one embodiment of the present disclosure may rapidly lower the temperature of the display apparatus 1000 in a high-temperature environment, does not require compensation depending on deterioration of operation of the display panel 300 when the display panel 300 is operated at a high temperature, and may thus be operated at low power. Therefore, the display apparatus 1000 according to the present disclosure may have an environmental, social, and governance (ESG) effect caused by eco-friendly, low power, and process optimization advantages.

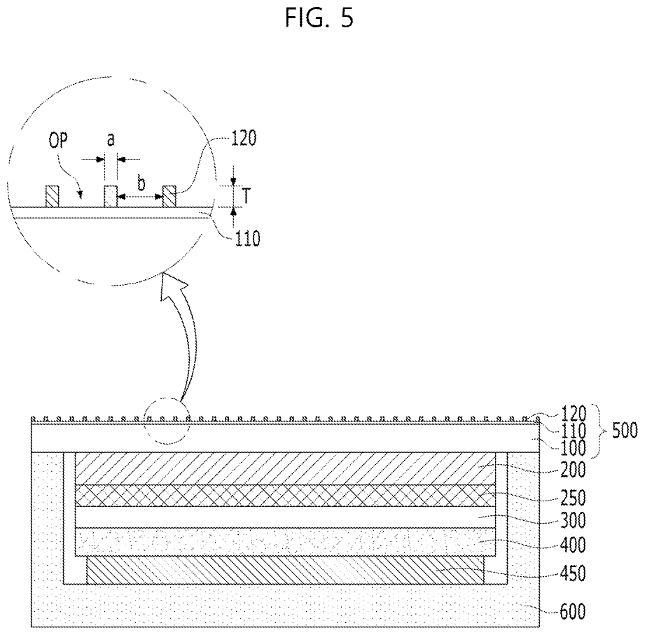

FIG. 5 is a cross-sectional view showing a display apparatus according to another embodiment of the present disclosure.

As shown in FIG. 5, the display apparatus according to another embodiment of the present disclosure may further include a housing 600 provided under the cover plate 100 and configured to receive the functional film 200, the polarizing plate 250, the display panel 300, the bottom plate 400, and the heat sink 450.

The housing 600 may be located on another surface of the display apparatus 1000 shown in FIG. 1 opposite the surface thereof facing the driver or the passenger seated in the front passenger seat. The housing 600 may be formed of a plastic molded member, or a metal member having designated rigidity.

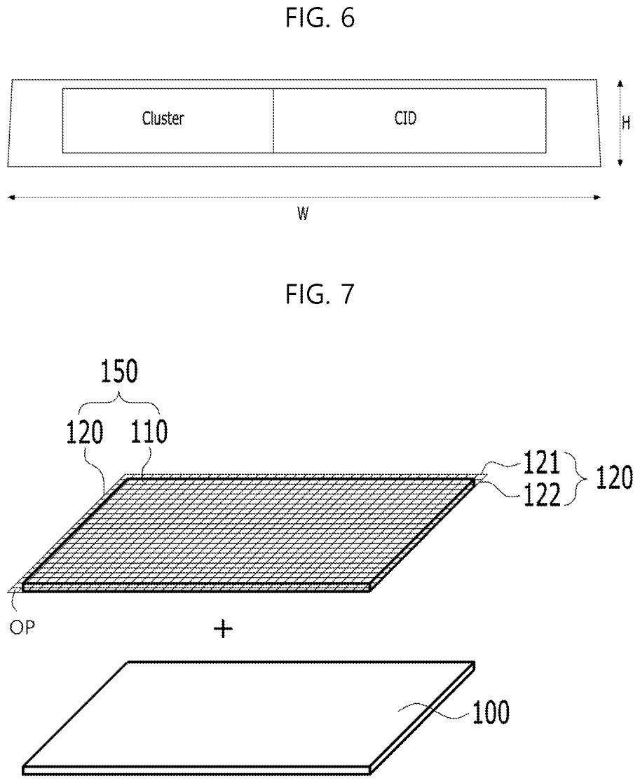

FIG. 6 is a plan view showing the cover plate of the display apparatus according to one embodiment of the present disclosure.

FIG. 6 show the cover plate according to one embodiment of the present disclosure, and particularly shows an example of the cover plate including a cluster and a central information display (CID) for vehicles provided in the cover plate.

As shown in FIGS. 1, and 6, the display apparatus provided in the vehicle according to one embodiment of the present disclosure allows the cover plate to correspond to the entirety of a dashboard extending laterally so as to exhibit the display function. Here, a horizontal length W of the cover plate is much greater than a vertical length H of the cover plate. In the case that the metal fine line unit is not provided on the cover plate, a warpage defect of the display apparatus may occur due to a heat dissipation efficiency difference between the cover plate and the heat sink located below the display panel, but the display apparatus according to one embodiment of the present disclosure has the metal fine line unit, and may thus ensure uniform heat dissipation between the front surface and the rear surface of the display panel so as to prevent occurrence of a warpage defect and to ensure reliability of the display apparatus.

FIG. 7 is a perspective view showing a method of manufacturing the cover plate module according to the present disclosure.

As shown in FIG. 7, the cover plate module according to one embodiment of the present disclosure is formed by forming the metal fine line unit 120 on the anti scattered film 110. For example, a metal fine line material is deposited on the anti scattered film 110, and a photoresist film pattern is formed by applying a photoresist film to the metal fine line material and then performing light exposure and development of the photoresist film using a mask including openings. Further, the metal fine line unit 120 having the first fine lines 121, and the second fine lines 122 arranged in the first and second directions to intersect each other and the openings OP provided between the first and second fine lines 121 and 122, as shown in FIG. 7, may be formed by removing exposed areas of the metal fine line material using the photoresist film pattern. The anti scattered film 110 and the patterned metal fine line unit 120 may be referred to as the protective film 155.

Further, the cover plate module 500 shown in FIG. 2 may be formed by adhering the protective film 155 to one surface of the cover plate 100.

Here, the metal fine line unit 120 may be formed on the anti scattered film 110 serving as the lower layer of the protective film 155 in the state in which the release film on the lower surface of the anti scattered film 110, which does not come into contact with the metal fine line unit 120, is maintained, and the anti scattered film 110 may be adhered to the cover plate 100 by removing the release film from the lower surface of the anti scattered film 110 and then adhering the lower surface of the anti scattered film 110, i.e., the exposed adhesive surface of the anti scattered film 110, to the cover plate 100.

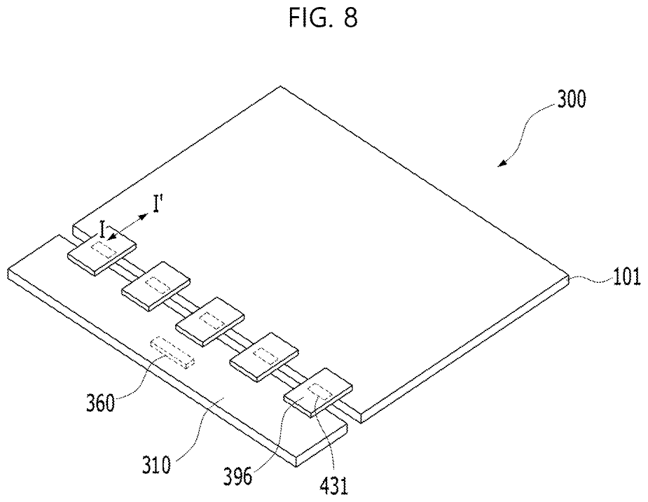

Hereinafter, the display panel according to one embodiment of the present disclosure will be described with reference to FIGS. 8 to 10.

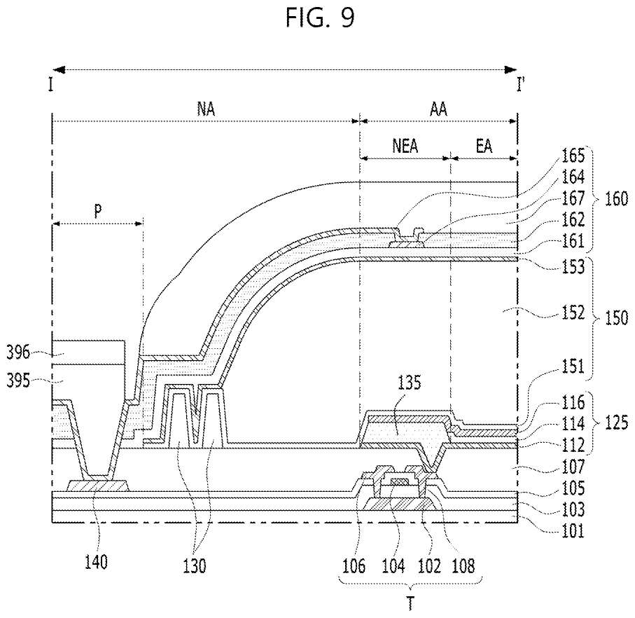

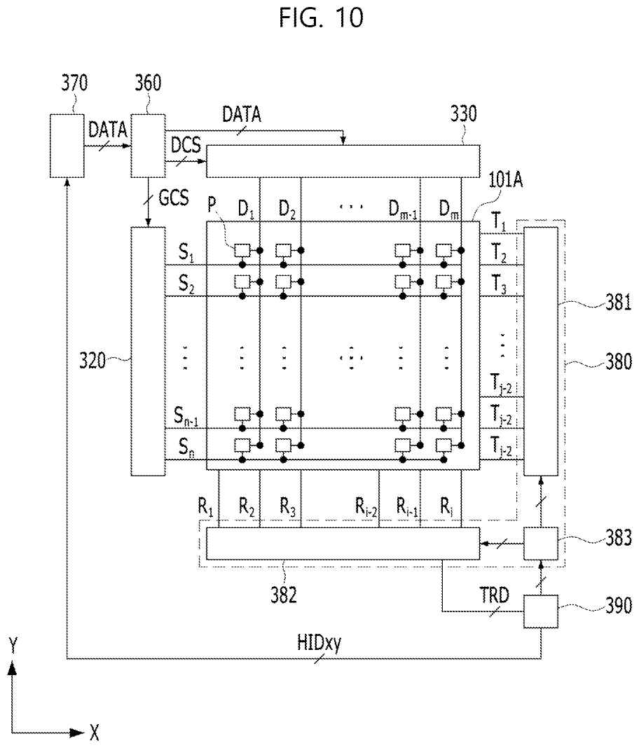

FIG. 8 is a perspective view showing the display panel of the display apparatus according to one embodiment of the present disclosure, FIG. 9 is a cross-sectional view taken along line I-I′ of FIG. 8, and FIG. 10 is a block diagram schematically showing the display panel shown in FIG. 8.

An image or a video may be reproduced on the display panel 300. The reproduced image or video may include navigation information necessary for driving, an image captured by a camera mounted in the vehicle, or other various contents necessary for the driver or passengers.

As shown in FIG. 10, the display apparatus according to one embodiment of the present disclosure includes the display panel 300, a scan driver 320, a data driver, a timing controller 360, a host system 370, a touch driver 380, and a touch coordinate calculator 390.

Although the display apparatus is implemented as an organic light emitting display (OLED) as one example in the description, the present disclosure is not limited thereto, and the display apparatus may be implemented as various display apparatuses, such as a liquid crystal display (LCD), an inorganic light emitting display, etc. The embodiments of the present disclosure are not limited thereto.

As shown in FIGS. 8, and 9, the display panel 300 may include a substrate 101, and a thin film transistor layer, a light emitting diode layer, an encapsulation layer, and a touch sensing layer, which are disposed on the substrate 101, but the embodiments of the present disclosure are not limited thereto.

The display panel 300 includes an active area 101A having a plurality of subpixels P provided therein so as to display an image, as shown in FIG. 10. Data lines D₁-Dₘ (m being a positive integer equal to or greater than 2) and scan lines S₁-Sₙ (n being a positive integer equal to or greater than 2) are formed on the display panel 300. The data lines D₁-Dₘ and the scan lines S₁-Sₙ may be formed to intersect each other. The scan lines S-S may be gate lines. The subpixels P may be formed in areas defined by intersection structures between the data lines D₁-Dₘ, and the scan lines S₁-Sₙ.

Each of the subpixels P on the display panel 300 may be connected to any one of the data lines D₁-Dₘ and any one of the scan lines S₁-Sₙ.

Each of the subpixels P on the display panel 300 may include a driving transistor configured to adjust current between a drain and a source depending on data voltage applied to a gate electrode, a scan transistor turned on depending on a scan signal from the scan line to supply data voltage from the data line to the gate electrode of the driving transistor, an organic light emitting diode configured to emit light depending on the current between the drain and the source of the driving transistor, and a capacitor configured to store voltage of the gate electrode of the driving transistor. Thereby, each of the subpixels P may emit light depending on current supplied to the organic light emitting diode.

The scan driver 320 receives a scan control signal GCS from the timing controller 360. The scan driver 320 supplies scan signals to the scan lines S₁-Sₙ depending on the scan control signal GCS.

The scan driver 320 may be formed in a gate in panel (GIP) type in a non-active area NA at one side of the active area AA of the display panel 300, or in non-active areas NA at both sides of the active area AA. Otherwise, the scan driver 320 may be manufactured into driving chips, for example, at least one circuit chip 431, may be mounted on a flexible circuit film 396 through tape automated bonding (TAB), and may be attached to the non-active area NA or the non-active areas NA provided at one side or both sides of the active area AA of the display panel 300. As shown in FIG. 8, at least one circuit chip 431 may be disposed at one side of the display panel 300.

The data driver 330 receives digital video data DATA and a data control signal DCS from the timing controller 360. The data driver 330 converts the digital video data DATA into analog positive/negative polarity data voltages, and supplies the analog positive/negative polarity data voltages to the data lines. For example, subpixels to which the data voltages are to be supplied are selected depending on the scan signals from the scan driver 320, and the data voltages are supplied to the selected subpixels.

The data driver 330 may include at least one circuit chip 431, as shown in FIG. 8. The at least one circuit chip 431 may be a source drive integrated circuit (IC). Each of the at least one circuit chip 431 may be mounted on a flexible circuit film 396 in a chip on film (COF) type or a chip on plastic (COP) type. The flexible circuit film 396 may be attached to pads provided in the non-active area NA of the display panel 300 using an anisotropic conductive film, and thereby, the at least one circuit chip 431 may be connected to the pad.

A printed circuit board 310 may be attached to the flexible circuit films 396. A plurality of circuits implemented as driving chips may be mounted on the printed circuit board 310. For example, the timing controller 360 may be mounted on the printed circuit board 310. The printed circuit board 310 may be a rigid printed circuit board or a flexible printed circuit board.

The timing controller 360 receives the digital video signal DATA and timing signals from the host system 370. The timing signals may include a vertical synchronization signal, a horizontal synchronization signal, a data enable signal, a dot clock and the like. The vertical synchronization signal defines one frame period. The horizontal synchronization signal defines one horizontal period necessary to supply data voltages to subpixels in one horizontal line. The data enable signal defines a period for which effective data is input. The dot clock is a signal which is repeated in a designated short period of time.

In order to control operation timing of the scan driver 320 and operation timing of the data driver 330, the timing controller 360 generates the data control signal DCS to control operation timing of the data driver 330 and the scan control signal GCS to control operation timing of the scan driver 320 based on the timing signals. The timing controller 360 outputs the scan control signal GCS to the scan driver 320, and outputs the digital video data DATA and the data control signal DCS to the data driver 330.

The host system 370 may be implemented as a navigation system, a set-top box, a DVD player, a Blu-ray player, a personal computer (PC), a home theater system, a broadcasting system, a phone system and the like. The host system 370 includes a system-on-chip (SoC) having a scaler, and converts the digital video data DATA of an input image into a format suitable to be displayed on the display panel 300. The host system 370 transmits the digital video data DATA and the timing signals to the timing controller 360.

First and second touch electrodes may be formed on the display panel 300, in addition to the data lines D₁-Dₘ and the scan lines S₁-Sₙ. The first touch electrodes may be provided to intersect the second touch electrodes. The first touch electrodes may be connected to a first touch driver 381 through first touch lines T₁-Tⱼ (j being a positive integer equal to or greater than 2). The second touch electrodes may be connected to a second touch driver 382 through second touch lines R₁-Rᵢ (i being a positive integer equal to or greater than 2). A touch sensor may be provided at each of intersections between the first touch electrodes and the second touch electrodes. The embodiments of the present disclosure are not limited thereto.

The touch driver 380 supplies a driving pulse to the first touch electrodes through the first touch lines T₁-Tⱼ, and senses capacitance changes of the respective touch sensors through the second touch lines R₁-Rᵢ. In FIG. 10, the first touch lines T₁-Tⱼ are described as lines Tₓ configured to supply the driving pulse, and the second touch lines R₁-Rᵢ are descried as lines Rₓ configured to sense the capacitance changes of the respective touch sensors, as one example.

The touch driver 380 includes the first touch driver 381, the second touch driver 382 and a touch controller 383. The first touch driver 381, the second touch driver 382 and touch controller 383 may be integrated into one read-out IC (ROIC).

The first touch driver 381 selects the first touch lines T₁-Tⱼ which are to output the driving pulses under the control of the touch controller 383, and supplies the driving pulses to the selected first touch lines T₁-Tⱼ. For example, the first touch driver 381 may sequentially supply the driving pulses to the first touch lines T₁-Tⱼ.

The second touch driver 382 selects the second touch lines R₁-Rᵢ, through which the capacitance changes of the corresponding touch sensors are to be received, and receives the capacitance changes of the touch sensors through the selected second touch lines R₁-Rᵢ. The second touch driver 382 converts the capacitance changes of the touch sensors received through the second touch lines R₁-Rᵢ into touch raw data TRD, which is digital data, through sampling.

The touch controller 383 may generate a Tx setup signal configured to set the first touch lines T₁-Tⱼ, to which the first touch driver 381 is to output the driving pulses, and an Rx setup signal configured to set the second touch lines R₁-Rᵢ, through which the second touch driver 382 is to receive touch sensor voltages. Further, the touch controller 383 generates timing control signals to control operation timing of the first touch driver 381 and operation timing of the second touch driver 382.

The touch coordinate calculator 390 receives the touch raw data TRD from the touch driver 380. The touch coordinate calculator 390 calculates one set of touch coordinates (plural sets of touch coordinates) based on a touch coordinate calculation method, and outputs touch coordinate data HID_{xy} including information about the set(s) of touch coordinates to the host system 370.

The touch coordinate calculator 390 may be implemented as a microcontroller unit (MCU). The host system 370 executes an application program associated with the coordinates touched by a user by analyzing the touch coordinate data HID_{xy} input from the touch coordinate calculator 390. The host system 370 transmits the digital video data DATA and the timing signals to the timing controller 360 depending on the executed application program.

The touch driver 380 may be included in the circuit chips 431 or manufactured as a separate driving chip, and may be mounted on the printed circuit board 310. Further, the touch coordinate calculator 390 may be manufactured as a driving chip and may be mounted on the printed circuit board 310.

As shown in FIG. 9, the display panel 300 of the display apparatus according to one embodiment of the present disclosure may include the substrate 101, the thin film transistors T, a planarization layer 107, the light emitting diodes 125, a bank 135, pad parts 140, dams 130, an encapsulation member 150 and touch parts 160.

The thin film transistors T are disposed on the substrate 101. The thin film transistors T transmit data voltage to a plurality of subpixels P.

The substrate 101 may support various elements of the display panel 300, and may be used as a plane on which the elements of the display panel 300 are provided. For example, the substrate 101 may comprise an insulating material, such as plastic or the like. When the substrate 101 comprises plastic, the substrate 101 may be referred as a plastic film or a plastic substrate. For example, the substrate 101 may comprise a film including one of polyimide-based polymer, a polyester-based polymer, a silicone-based polymer, an acrylic polymer, a polyolefin-based polymer, and copolymers thereof. Among these materials, polyimides may be applied to high-temperature processes and may be coated, and may thus mainly be used as plastic substrates. An array substrate is referred to as a concept including devices and functional layers disposed on the substrate 101, for example, switching TFTs, driving TFTs connected to the switching TFTs, the light emitting diodes 125 connected to the driving TFTs, the encapsulation member 150 and the like.

A buffer layer may be located on the substrate 101. The buffer layer is a functional layer configured to protect the thin film transistors (TFTs) T from impurities, such as alkali ions leaking from the substrate 101 or the layers provided thereunder. The buffer layer may comprise a single layer or multilayer structure including silicon oxide (SiOₓ) or silicon nitride (SiNₓ), but the embodiments of the present disclosure are not limited thereto.

The thin film transistors T may be disposed on the substrate 101 or the buffer layer. The thin film transistor T may include an active layer 102, a gate insulating layer 103, a gate electrode 104, an interlayer insulating layer 105, a source electrode 106 and a drain electrode 108. The active layer 102 is located on the substrate 101 or the buffer layer. The active layer 102 may comprise polysilicon (p-Si), and in this case, a designated area of the active layer 102 may be doped with impurities. Otherwise, the active layer 102 may comprise amorphous silicon (a-Si), or may comprise various organic semiconductor materials, such as pentacene. Alternatively, the active layer 102 may comprise an oxide semiconductor material.

The gate electrode 104 may be disposed on the upper surface or the lower surface of the active layer 102 depending on the structure of the thin film transistor T. The gate electrode 104 may comprise various conductive materials, for example, at least one of magnesium (Mg), aluminum (Al), nickel (Ni), chromium (Cr), molybdenum (Mo), tungsten (W), gold (Au), or alloys thereof. The embodiments of the present disclosure are not limited thereto.

The gate insulating layer 103 may be disposed between the active layer 102 and the gate electrode 104. The gate insulating layer 103 comprise an insulating material so as to isolate the gate electrode 104 and the active layer 102 from each other. For example, the gate insulating layer 103 may comprise a single layer or multilayer structure including silicon oxide (SiOₓ) or silicon nitride (SiNₓ), but the embodiments of the present disclosure are not limited thereto.

The source electrode 106 and the drain electrode 108, which are conductively connected to the active layer 102, and are spaced apart from each other, may be disposed on the interlayer insulating layer 105. The source electrode 106 and the drain electrode 108 may comprise a conductive material, for example, at least one of copper (Cu), aluminum (Al), molybdenum (Mo), titanium (Ti), or alloys thereof, but are not limited thereto.

Depending on the structure of the thin film transistor T, the interlayer insulating layer 105 may be disposed between the gate electrode 104 and the source and drain electrodes 106 and 108 so as to isolate the gate electrode 104 and the source and drain electrodes 106 and 108 from each other, but the embodiments of the present disclosure are not limited thereto.

The planarization layer 107 may be located on the thin film transistors T. The planarization layer 107 protects the thin film transistors T, and planarizes the upper surfaces of the thin film transistors T. The planarization layer 107 may be disposed throughout the active area AA, and may not be disposed in the entirety or some areas of the non-active area NA. The planarization layer 107 may be in various types. The planarization layer 107 may comprise an organic insulating film formed of benzocyclobutene (BCB) or acryl. Or The planarization layer 107 may comprise an inorganic insulating film such as silicon nitride (SiNₓ) or silicon oxide (SiOₓ). The planarization layer 107 may comprise a single layer, double layer or multilayer structure, i.e., may be variously modified. The embodiments of the present disclosure are not limited thereto. The planarization layer 107 may include a contact hole configured to conductively connect the thin film transistor T to the light emitting diode 125.

The light emitting diodes 125 are disposed on the planarization layer 107. The light emitting diode 125 may be a self-emissive element which emits light, and may be driven by voltage supplied from the transistor and the like. The light emitting diode 125 may include a first electrode 112, a light emitting layer 114, and a second electrode 116.

For example, the light emitting diode 125 may include the first electrode 112 positioned on the planarization layer 107, the light emitting layer 114 located on the first electrode 112, and the second electrode 116 located on the light emitting layer 114. For example, the light emitting diode 125 may be a self-emissive element which emits light, and may be driven by voltage supplied from the thin film transistor (TFT) and the like.

The first electrode 112 is conductively connected to the drain electrode 108 of the driving thin film transistor T through the contact hole CH. The first electrode 112 may comprise a conductive material which may supply holes to the light emitting layer 114. When the display panel 300 is a top emission type, the first electrode 112 may comprise an opaque conductive material having high reflectance, and the second electrode 116 may comprise a transmissive electrode or a transflective electrode. For example, the first electrode 112 may comprise at least one of silver (Ag), aluminum (Al), gold (Au), molybdenum (Mo), tungsten (W), chromium (Cr), or alloys thereof. Further, the second electrode 116 opposite the first electrode 112 may be formed as a thin electrode comprising an indium tin zinc oxide (ITZO)-based, zinc oxide (ZnO)-based or tin oxide (TO)-based transparent conductive oxide, or a transflective metal including at least one of silver, magnesium, aluminum, ytterbium, or alloys thereof. However, the embodiments of the present disclosure are not limited thereto.

The bank 135 is disposed on the first electrode 112, and the planarization layer 107. The bank 135 is an insulating layer configured to divide adjacent subpixels from each other. The bank 135 may be disposed to open a part of the first electrode 112, and the bank 135 may comprise an organic insulating material disposed to cover the edge of the first electrode 112.

The bank 135 is provided in a remaining area other than an emissive area EA. Thereby, the bank 135 may have a bank hole configured to expose the first electrode 112 corresponding to the emissive area EA. The bank 135 may comprise an inorganic insulating material, such as silicon nitride (SiNₓ) or silicon oxide (SiOₓ), or an organic insulating material, such as BCB, an acrylic resin or an imide-based resin.

The light emitting layer 114 is disposed on the first electrode 112 exposed by the bank 135. The light emitting layer 114 may include an emissive layer, an electron injection layer, an electron transport layer, a hole transport layer, a hole injection layer and the like. Here, the emissive layer may be provided in a single emissive layer structure configured to emit one color of light, or a plurality of emissive layers may be provided to emit white light through combination of colors of light emitted by the plurality of emissive layers.

Referring to FIG. 9, the light emitting layer 114 disposed in the respective subpixels is illustrated as being separated by the respective subpixels, but are not limited thereto. For example, the entirety or a part of the light emitting layer 114 may be provided as one layer throughout the plurality of subpixels.

The second electrode 116 may be disposed on the light emitting layer 114. The second electrode 116 comprises a conductive material which may supply electrons to the light emitting layer 114. For example, the second electrode 116 may be formed as a thin electrode comprising an indium tin zinc oxide (ITZO)-based, zinc oxide (ZnO)-based or tin oxide (TO)-based transparent conductive oxide, or a transflective metal including at least one of silver, magnesium, aluminum, ytterbium, or alloys thereof. However, the embodiments of the present disclosure are not limited thereto. When the display panel 300 is a top emission type, the second electrode 116 may be formed as a thin electrode comprising a transparent conductive material, such as indium tin oxide (ITO) or indium zinc oxide (IZO), or a transflective metal alloy, such as an MgAg alloy, and may thus emit light generated by the light emitting layer 114 upwards.

Although FIG. 9 illustrates that the second electrode 116 is disposed throughout the respective subpixels, the second electrode 116 may be disposed to be separated by the respective subpixels, but are not limited thereto.

The light emitting layer 114 may be an organic light emitting layer comprising an organic light emitting material, but is not limited thereto. For example, the light emitting layer 114 may comprise an inorganic light emitting layer including an inorganic semiconductor layer including a quantum dot material or a nitride semiconductor, or an organic-inorganic mixed light emitting layer. In some cases, the light emitting diodes 125 may be micro-LEDs.

The active area AA may include a plurality of emissive areas EA, and a non-emissive area NEA disposed among the plurality of emissive areas EA.

Respective areas in which the plurality of light emitting diodes 125 is disposed may be the plurality of emissive areas EA. Each of the plurality of emissive areas EA may be an area which emits one color of light independently, and corresponds to a corresponding one of the plurality of subpixels, and the bank 135 is not disposed in this area. For example, the plurality of emissive areas EA may include red light emissive areas, green light emissive areas and blue light emitting areas, but is not limited thereto. The plurality of emissive areas EA may be arranged to be spaced apart from each other, for example, may be arranged in a lattice provided in row and column directions, but is not limited thereto.

An area in which the plurality of light emitting diodes 125 is not disposed may be the non-emissive area NEA. The non-emissive area NEA is disposed among the plurality of emissive areas EA, and the bank 135 may be disposed in the non-emissive area NEA. The non-emissive area NEA is disposed to surround the plurality of emissive areas EA, and may thus be provided in a matrix.

The dams 130 are disposed in the non-emissive area NEA. For example, the dams 130 may be disposed on the substrate 101 in the non-emissive area NEA. The dams 130 are disposed to control spread of an organic encapsulation layer 152 of the encapsulation member 150 disposed to cover the active area AA. For example, the dams 130 may suppress overflow of the organic encapsulation layer 152 of the encapsulation member 150. At least one dam 130 may be configured, and the number of the dams 130 disposed is not limited.

The pad parts 140 are disposed in the non-active area NA. The pad parts 140 may be disposed outside the dams 130. Signals may be input to the circuits, the circuit chips and the like provided on the substrate 101 through the pad parts 140. For example, the pad parts 140 may supply signals supplied from the outside to the circuits, the circuit chips and the like on the substrate 101. For example, the pad parts 140 may supply signals to drive the touch parts 160 to the touch parts 160, and may receive signals about a user's touch input from the touch parts 160.

The encapsulation member 150 is disposed on the light emitting diodes 125. The encapsulation member 150 is a sealing member configured to protect the light emitting diode 125 from external moisture, oxygen, impact and the like, so as to prevent luminescent materials and electrode materials of the light emitting diode 125 from being oxidized. The encapsulation member 150 may be disposed to cover the entirety of the active area AA in which the light emitting diodes 125 are disposed, and may be disposed to cover a portion of the non-active area NA extending from the active area AA. The encapsulation member 150 may include a first inorganic encapsulation layer 151 comprise an inorganic material, the organic encapsulation layer 152 disposed on the first inorganic encapsulation layer 151 and comprising an organic material, and a second inorganic encapsulation layer 153 disposed on the organic encapsulation layer 152.

The first inorganic encapsulation layer 151 seals the active area AA, and thus protects the light emitting diodes 125 from oxygen, and moisture penetrating the active area AA. The first inorganic encapsulation layer 151 may be disposed from the active area AA to a portion of the non-active area NA extending from the active area AA, and may be disposed to cover the dams 130 in the non-active area NA. The first inorganic encapsulation layer 151 may comprise an inorganic material, for example, an inorganic material, such as silicon nitride (SiNₓ), silicon oxide (SiOₓ) or silicon oxynitride (SiON), but is not limited thereto.

The organic encapsulation layer 152 is disposed on the first inorganic encapsulation layer 151. The organic encapsulation layer 152 configured to planarize the upper surface of the first inorganic encapsulation layer 151 may fill cracks in the first inorganic encapsulation layer 151, and may planarize the upper surfaces of foreign substances when foreign substances are located on the first inorganic encapsulation layer 151. The organic encapsulation layer 152 may be disposed from the active area AA to a portion of the non-active area NA extending from the active area AA, and may be disposed inside the dams 130. The organic encapsulation layer 152 may employ an epoxy-based or acrylic polymer, but is not limited thereto.

The second inorganic encapsulation layer 153 is disposed on the organic encapsulation layer 152. The second inorganic encapsulation layer 153 may seal the organic encapsulation layer 152 together with the first inorganic encapsulation layer 151 in a manner in which the second inorganic encapsulation layer 153 comes into contact with the first inorganic encapsulation layer 151 at the edge of the display panel 300. The second inorganic encapsulation layer 153 may be disposed from the active area AA to a portion of the non-active area NA extending from the active area AA, and may be disposed to come into contact with the first inorganic encapsulation layer 151 disposed in the non-active area NA. The second inorganic encapsulation layer 153 may comprise an inorganic material, for example, silicon nitride (SiNₓ), silicon oxide (SiOₓ) or silicon oxynitride (SiON), but is not limited thereto.

Although FIG. 9 illustrates that the encapsulation member 150 includes the first inorganic encapsulation layer 151, the organic encapsulation layer 152, and the second inorganic encapsulation layer 153, the number of inorganic encapsulation layers and the number of organic encapsulation layers included in the encapsulation member 150 are not limited thereto.

The touch parts 160 may be disposed on the encapsulation member 150. The touch parts 160 may be disposed in the active area AA in which the light emitting diodes 125 are disposed, and may sense a touch input. The touch parts 160 may sense external touch information using a user's finger, a touch pen or the like. Each of the touch parts 160 may include a first protective layer 161, a second protective layer 162, an organic insulating layer 167, a first touch electrode 164 and a second touch electrode 165.

The first protective layer 161 may be disposed on the encapsulation member 150. The first protective layer 161 may come into contact with the second inorganic encapsulation layer 153 of the encapsulation member 150. The first protective layer 161 may comprise an inorganic material. For example, the first protective layer 161 may comprise an inorganic material, such as silicon nitride (SiNₓ), silicon oxide (SiOₓ) or silicon oxynitride (SiON), but the embodiments of the present disclosure are not limited thereto.

The first touch electrodes 164 of the touch parts 160 are disposed on the first protective layer 161. The first touch electrodes 164 are disposed in the non-emissive area NEA on the first protective layer 161. The respective first touch electrodes 164 of the touch parts 160 may be spaced apart from one another so as to be arranged in the X-axis direction and the Y-axis direction. For example, the respective first touch electrodes 164 of the touch parts 160 may be provided in a plurality of patterns spaced apart from one another so as to be arranged in the X-axis direction and a plurality of patterns spaced apart from one another so as to be arranged in the Y-axis direction. The first touch electrodes 164 supply touch driving signals configured to drive the touch parts 160. Further, the first touch electrodes 164 may transmit touch information sensed by the touch parts 160 to a driving IC. The first touch electrodes 164 may comprise a structure in a mesh type, but are not limited thereto. The first touch electrodes 164 may comprise a metal material, but are not limited thereto.

The second protective layer 162 may be disposed on the first touch electrodes 164 and the first protective layer 161. The second protective layer 162 may prevent short circuit between the first touch electrodes 164 disposed adjacent to each other.

The second touch electrodes 165 of the touch parts 160 may be disposed on the second protective layer 162. The second protective layer 162 may comprise an inorganic material. For example, the second protective layer 162 may comprise an inorganic material, such as silicon nitride (SiNₓ), silicon oxide (SiOₓ) or silicon oxynitride (SiON), without being limited thereto.

The pad parts 140 and the second touch electrodes 165 may be conductively connected to the flexible circuit film 396 through a conductive adhesive layer 395.

Referring to FIG. 9, open areas P in which the first protective layer 161, the second protective layer 162 and the organic insulting layer 167 are not disposed may be provided on the pad parts 140. Because the uppermost metal electrode should be exposed to the outside so as to adhere the flexible circuit film 396 of FIG. 8 to the pad parts 140. The pad parts 140 and the second touch electrodes 165 may be conductively connected to the flexible circuit film 396 through the conductive adhesive layer 395.

In the display apparatus according to one embodiment of the present disclosure, the metal fine line unit 120 in the cover plate module may be disposed not to overlap the above-descried first and second touch electrodes 164 and 165, so as to prevent interference with the first and second touch electrodes 164 and 165 during driving of the first and second touch electrodes 164 and 165.

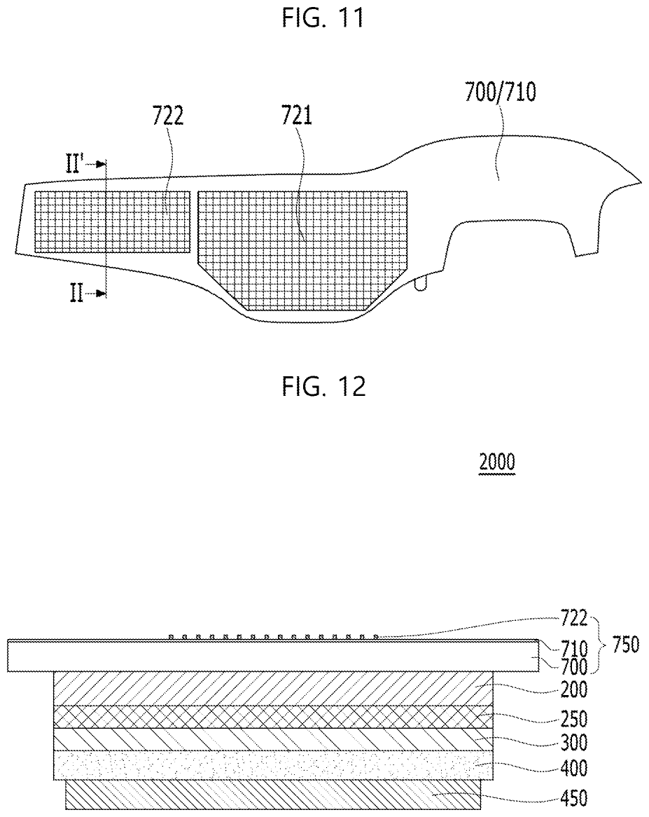

FIG. 11 is a plan view showing a display apparatus according to another embodiment of the present disclosure, and FIG. 12 is a cross-sectional view taken along line II-II′ of FIG. 11.

As shown in FIG. 11, a cover plate module 750 of a display apparatus 2000 according to anther embodiment of the present disclosure may include a first metal fine line unit 721 and a second metal fine line unit 722 corresponding to some areas of a cover plate 700 and an anti scattered film 710 which are stacked.

For example, the first metal fine line unit 721 may be provided to correspond to a central information display (CID) for vehicles, and the second metal fine line unit 722 may be provided to correspond to a cluster. In the display apparatus 2000 according to another embodiment of the present disclosure, the first and second metal fine line units 721 and 722 are locally located in areas in which the display panel 300 is disposed and thus on which heat is concentrated.

The cover plate 700 and the anti scattered film (or shatterproof film) 710 may have the same size, or the cover plate 700 may have a greater size than the anti scattered film 710 so as to protrude slightly farther outwards than the anti scattered film 710. The anti scattered film 710 serves to prevent the cover plate 70 from shattering due to physical impact applied to the cover plate 700, and may have a greater size than the sum total of the sizes of the first and second metal fine line units 711 and 712 of the display apparatus 2000 according to this embodiment of the present disclosure, as shown in FIGS. 11 and 12.

Further, the cover plate 700 shown in FIG. 11 has a bilaterally asymmetrical shape in which an upper part of a right side protrudes upwards and a lower part of the right side is concave. Such a shape is only one example indicating the cover plate 700 having an irregular shape. In a part of the cover plate module 750 shown in FIG. 11, for example, in the right area of the cover plate module 750, only the cover plate 700 and the anti scattered film 710 may be stacked without any metal fine line unit provided thereon. However, all of the functional film 200, the polarizing plate 250, the display panel 300, the bottom plate 400 and the heat sink 450 may be omitted from the lower surface of the area of the cover plate 700 in which the first and second metal fine line units 721 and 722 are not provided, and therefore, there may be no heat dissipation difference between the front surface of the cover plate module 750 and an element below the cover plate module 750 in this area.

The display apparatus 2000 according to another embodiment of the present disclosure includes the cover plate module 750 in which the metal fine line units 721 and 722 are applied to the irregular-shaped cover plate 700, and thus, may control the cover plate module 750 so as to have similar heat dissipation to the heat sink 450, and may offset a heat dissipation difference between the front and rear surfaces of the display panel 300 so as to prevent the display apparatus 2000 from warping in a specific direction.

Here, a first display panel and a second display panel corresponding to the first metal fine line unit 721 and the second metal fine line unit 722 provided in different areas of the cover plate 700 may be provided under the cover plate 700. Therefore, the first display panel and the second display panel provided under the cover plate 700 of FIG. 11 may have different sizes.

In the display apparatus 2000 according to another embodiment of the present disclosure, the cover plate 700 is not limited to the irregular shape shown in FIG. 11.

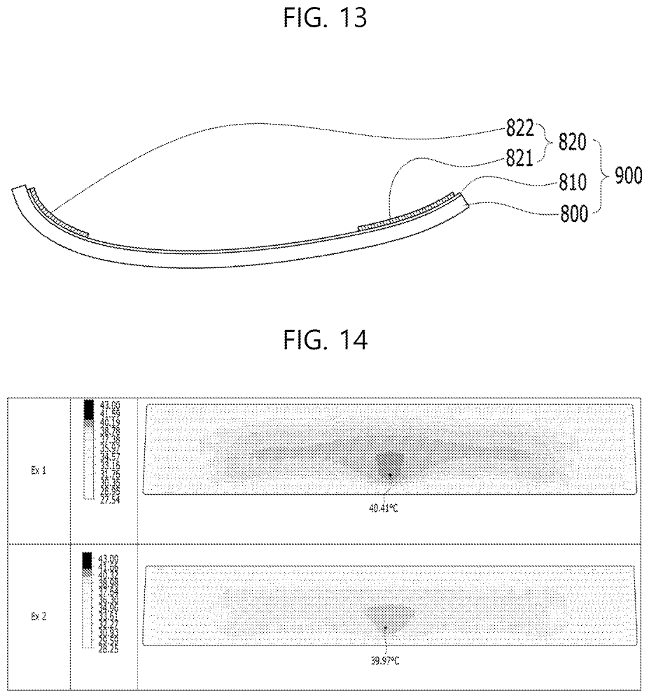

FIG. 13 is a cross-sectional view showing a cover plate module (cover plate unit) according to yet another embodiment of the present disclosure.

As shown in FIG. 13, a cover plate module 900 according to yet another embodiment of the present disclosure is configured such that a cover plate 800 includes areas having different curvatures. The cover plate module 900 includes an anti scattered film 810 provided on the cover plate 800 having a curved shape, and metal fine line units 820 provided on areas of the anti scattered film 810 having the different curvatures.

The cover plate module 900 shown in FIG. 13 includes the metal fine line units 820 including a first metal fine line unit 821 and a second metal fine line unit 822 provided on the areas of the anti scattered film 810 having the different curvatures so as to be spaced apart from each other. The anti scattered film 810 may be provided between the cover plate 800 and the metal fine line units 820. The anti scattered film 810 may be provided to have a size corresponding to the size of the cover plate 800, as shown in FIG. 13, or may be provided to have sizes corresponding to the sizes of the metal fine line units 820, i.e., the first metal fine line unit 821 and the second metal fine line unit 822.

As such, the display apparatus including the cover plate module 900 according to yet another embodiment of the present disclosure has the metal fine line units 820 provided on at least areas having the maximum curvature, and may exhibit similar heat dissipation effects through both the front and rear surfaces of the display apparatus, thereby being capable of effectively preventing a warpage defect of the display apparatus. In some cases, in the display apparatus according to one embodiment of the present disclosure, a metal fine line unit may be selectively provided in an area having the maximum curvature.

According to one embodiment of the present disclosure, when touch function parts (for example, the functional film 200 of FIG. 2 or the touch parts 160 of FIG. 9) are provided between the cover plate 100 (in FIG. 2) and the display panel 300, the areas, in which the metal fine line units 820 are located, and the touch function parts may be provided not to overlap each other, so as to prevent interference between the touch function parts and the metal fine line units 820 during driving of the touch function parts.

Hereinafter, effects of presence and absence of a metal fine line unit at the uppermost part of a cover plate module through tests will be described. Test Example 1 Ex1 was performed on a display apparatus including a cover plate module without the metal fine line unit shown in FIG. 2 on the uppermost layer of the cover plate module, and Test Example 2 Ex2 was performed on a display apparatus having the structure shown in FIG. 2.

FIG. 14 is a view showing temperature changes of the cover plate modules of the display apparatuses according to Test Example 1 and Test Example 2 of the present disclosure after a high-temperature driving test.

In Test Example 1 and Test Example 2, after the display apparatuses were manufactured by bonding the respective cover plate modules to lower elements, the display apparatuses were driven at a temperature of about 60-70° C. for 12 hours to 24 hours, and thereafter, temperature changes of the respective cover plate modules were measured after a designated time.

As shown in FIG. 14, it may be confirmed that the temperature of the center of the cover plate module according to Test Example 2 Ex2 was relatively low, i.e., 39.97° C., whereas the temperature of the center of the cover plate module according to Test Example 1 Ex1 was 40.41° C.

In addition, it may be confirmed that, whereas a temperature difference between the center and the edge of the cover plate module according to Test Example 1 Ex1 was severe due to low thermal conductivity of the cover glass itself of the display apparatus after the high-temperature driving test, heat distribution from the center to the edge of the cover plate module according to Test Example 2 Ex2 was gentle. Thereby, it may be confirmed that, when the metal fine line unit according to this embodiment is applied, as in Test Example 2 Ex2, heat dissipation effects in the horizontal direction are excellent, a temperature difference between the center and the edge of the cover plate module is reduced, and thus, downward warpage or sagging of the display apparatus due to a heat dissipation difference between the cover plate module and the heat sink below the display panel may be prevented.

A cover plate module according to one embodiment of the present disclosure may include a cover plate including a transparent part, an anti scattered film located on the cover plate, and a metal fine line unit provided on the anti scattered film.

According to one embodiment of the present disclosure, the metal fine line unit may include a plurality of first fine lines and a plurality of second fine lines arranged in a first direction and a second direction and configured to intersect each other, and a plurality of openings provided between the plurality of first fine lines and the plurality of second fine lines configured to intersect each other.

According to one embodiment of the present disclosure, a width of the plurality of openings may be greater than a width of each of the plurality of first fine lines and the plurality of second fine lines.

According to one embodiment of the present disclosure, the plurality of first fine lines and the plurality of second fine lines may have a width of 5 μm to 10 μm and a thickness of 1 μm to 3 μm.

According to one embodiment of the present disclosure, a first surface of the anti scattered film may come into contact with the cover plate, and a second surface of the anti scattered film may come into contact with the metal fine line unit.

According to one embodiment of the present disclosure, the metal fine line unit may comprise a metal or a metal alloy including at least one of copper, aluminum, gold, silver, or tungsten.

According to one embodiment of the present disclosure, the cover plate may have a plurality of areas having curvatures, and the metal fine line unit may be provided on at least an area having a maximum curvature out of the plurality of areas having the curvatures so as to be spaced apart from one another.

According to one embodiment of the present disclosure, a planar area of the metal fine line unit may be less than a planar area of the anti scattered film.

A display apparatus according to one embodiment of the present disclosure may include at least one display panel, a cover plate module provided on the least one display panel and including a cover plate and a metal fine line unit provided on the cover plate, a bottom plate provided under the at least one display panel so as to support the at least one display panel, and a heat sink located under the bottom plate.

According to one embodiment of the present disclosure, the metal fine line unit of the cover plate module may include a metal having higher thermal conductivity than the heat sink.

According to one embodiment of the present disclosure, the cover plate module may further include an anti scattered film between the cover plate and the metal fine line unit.

According to one embodiment of the present disclosure, the metal fine line unit may include a plurality of first fine lines and a plurality of second fine lines arranged in a first direction and a second direction and configured to intersect each other, and a plurality of openings provided between the plurality of first fine lines and the plurality of second fine lines configured to intersect each other.

According to one embodiment of the present disclosure, a width of the plurality of openings may be greater than a width of each of the plurality of first fine lines and the plurality of second fine lines.

According to one embodiment of the present disclosure, a first surface of the anti scattered film may come into contact with the cover plate, and a second surface of the anti scattered film may come into contact with the metal fine line unit.

According to one embodiment of the present disclosure, the at least one display panel may include a first display panel and a second display panel configured to correspond to different areas of the cover plate, and the first display panel and the second display panel may have different sizes.

According to one embodiment of the present disclosure, the metal fine line unit may be provided to correspond to each of the first display panel and the second display panel.

According to one embodiment of the present disclosure, the metal fine line unit may comprise a metal or a metal alloy including at least one of copper, aluminum, gold, silver, or tungsten.

According to one embodiment of the present disclosure, the cover plate may have a plurality of areas having curvatures and spaced apart from each other, and the metal fine line unit may be provided on at least an area having a maximum curvature out of the plurality of areas having the curvatures.

According to one embodiment of the present disclosure, the cover plate may include a plurality of areas having different curvatures, and the metal fine line unit may be provided to correspond to each of the plurality of areas having the different curvatures so as to be spaced apart from one another.

As is apparent from the above description, a cover plate module and a display apparatus including the same according to the present disclosure have the following effects.

According to one embodiment, metal fine lines are provided on a cover plate, and may thus increase a heat dissipation rate of the front surface of the cover plate using thermal conductivity of a metal.

According to one embodiment of the present disclosure, heat dissipation rates of the front and rear surfaces of the cover plate are equalized, and may thus prevent the display apparatus from warping or sagging in a specific direction.

According to one embodiment of the present disclosure, openings having a greater width (spacing) than the width of the metal lines are provided in a metal fine line unit configured to perform heat dissipation so as to maintain a transmittance of a designated level or more, and may thus not deteriorate the display function of a display panel coupled to the cover plate module.

According to one embodiment of the present disclosure, the metal fine line unit is provided on each of a plurality of areas having curvatures of the cover plate or is provided on at least an area having the maximum curvature of the cover plate, may exhibit similar heat dissipation effects through both the front and rear surfaces of the display apparatus, and may thus effectively preventing a warpage defect of the display apparatus.

According to one embodiment of the present disclosure, the metal fine line unit may comprise a metal used in the display apparatus field, and may use eco-friendly materials without using hazardous substances. Further, the temperature of the display apparatus may be rapidly lowered in a high-temperature environment, compensation for deterioration of operation of the display panel is not required when the display panel is operated at a high temperature, and thus, the display apparatus may be operated at low power. Therefore, the display apparatus according to the present disclosure may have an environmental, social, and governance (ESG) effect caused by eco-friendly, low power, and process optimization advantages.

Although the embodiments of the present disclosure have been described with reference to the accompanying drawings, it is to be understood that various modifications thereof are apparent to those skilled in the art within the spirit and scope of the present disclosure. Therefore, the embodiments of the present disclosure are disclosed for illustrative purposes but are not intended to limit the spirit and scope of the present disclosure, and the spirit and scope of the present disclosure are not limited by the embodiments. Accordingly, Therefore, it is to be understood that the embodiments described herein are exemplary but are not intended to be limiting. The scope of the present disclosure is defined not by the detailed description, but by the claims and their equivalents, and all variations within the scope of the claims and their equivalents are to be construed as being included in the spirit and scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A cover plate module comprising:
a cover plate comprising a transparent part;
an anti scattered film located on the cover plate; and
a metal fine line assembly provided on the anti scattered film.

2. The cover plate module according to claim 1, wherein the metal fine line assembly comprises:
a plurality of first fine lines arranged in a first direction;
a plurality of second fine lines arranged in a second direction transvers to the first direction; and
a plurality of openings between the plurality of first fine lines and the plurality of second fine lines.

3. The cover plate module according to claim 2, wherein a width of the plurality of openings is greater than a width of each of the plurality of first fine lines and the plurality of second fine lines.

4. The cover plate module according to claim 1, wherein a first surface of the anti scattered film is in contact with the cover plate, and a second surface of the anti scattered film is in contact with the metal fine line assembly.

5. The cover plate module according to claim 1, wherein the metal fine line assembly comprises a metal or a metal alloy comprising at least one of copper, aluminum, gold, silver, or tungsten.

6. The cover plate module according to claim 1, wherein the cover plate has a plurality of areas having curvatures, and the metal fine line assembly is disposed on at least an area having a maximum curvature to be spaced apart from one another.

7. The cover plate module according to claim 1, wherein a planar area of the metal fine line assembly is less than a planar area of the anti scattered film.

8. A display apparatus comprising:
at least one display panel;
a cover plate module on the least one display panel, the cover plate module comprising a cover plate and a metal fine line assembly on the cover plate;
a bottom plate under the at least one display panel to support the at least one display panel; and
a heat sink under the bottom plate.

9. The display apparatus according to claim 8, wherein the metal fine line assembly comprises a metal having higher thermal conductivity than the heat sink.

10. The display apparatus according to claim 8, wherein the cover plate module further comprises an anti scattered film between the cover plate and the metal fine line assembly.

11. The display apparatus according to claim 8, wherein the metal fine line assembly comprises:
a plurality of first fine lines arranged in a first direction;
a plurality of second fine lines arranged in a second direction transverse to the first direction; and
a plurality of openings between the plurality of first fine lines and the plurality of second fine lines.

12. The display apparatus according to claim 11, wherein a width of the plurality of openings is greater than a width of each of the plurality of first fine lines and the plurality of second fine lines.

13. The display apparatus according to claim 10, wherein a first surface of the anti scattered film is in contact with the cover plate, and a second surface of the anti scattered film is in contact with the metal fine line assembly.

14. The display apparatus according to claim 8, wherein the at least one display panel comprises a first display panel and a second display panel to correspond to different areas of the cover plate, and the first display panel and the second display panel have different sizes.

15. The display apparatus according to claim 14, wherein the metal fine line assembly is provided to correspond to each of the first display panel and the second display panel.

16. The display apparatus according to claim 8, wherein the metal fine line assembly comprises a metal or a metal alloy comprising at least one of copper, aluminum, gold, silver, or tungsten.

17. The display apparatus according to claim 8, wherein the cover plate has a plurality of areas having curvatures and spaced apart from each other, and the metal fine line assembly is disposed on at least an area having a maximum curvature.

18. The display apparatus according to claim 8, wherein the cover plate includes a plurality of areas having different curvatures, and the metal fine line assembly is provided to correspond to each of the plurality of areas having the different curvatures to be spaced apart from one another.

19. The display apparatus according to claim 8, further comprising a touch function part between the cover plate and the display panel, and the metal fine line assembly does not overlap the touch function part.

20. An automobile comprising:
a body having a motor mounted therein;
at least one display panel in the body;
a cover plate module on the least one display panel, the cover plate module comprising a cover plate and a metal fine line assembly on the cover plate;
a bottom plate under the at least one display panel to support the at least one display panel; and
a heat sink under the bottom plate.
